(19) United States
(12) Patent Application Publication
(10) Pub. No.: US 2024/0145624 A1
(43) Pub. Date: May 2, 2024

(54) ENHANCED QUANTUM DOT COLOR CONVERSION LAYER FABRICATION AND INTEGRATION FOR MICROLED BACKPLANE

(71) Applicant: Applied Materials, Inc., Santa Clara, CA (US)

(72) Inventors: Peiwen LIU, Fremont, CA (US); Hyunsung BANG, Alzenau (DE); Jianfeng SUN, Milpitas, CA (US); Lisong XU, Santa Clara, CA (US); Zhiyong LI, San Jose, CA (US); Sivapackia GANAPATHIAPPAN, Los Altos, CA (US); Mingwei ZHU, San Jose, CA (US); Hou T. NG, Campbell, CA (US); Nag. B. PATIBANDLA, Santa Clara, CA (US)

(21) Appl. No.: 18/493,426

(22) Filed: Oct. 24, 2023

Related U.S. Application Data
(60) Provisional application No. 63/381,423, filed on Oct. 28, 2022.

(51) Int. Cl. H01L 33/06; H01L 33/50; H01L 33/52; H01L 33/58

(52) U.S. Cl. CPC H01L 33/06; H01L 33/502; H01L 33/52; H01L 33/58; H01L 2933/0041

(57) ABSTRACT

A pixel herein includes a color panel, a light emitting diode (LED) panel, and an adhesive layer disposed between the color panel and the LED panel. The color panel includes a transparent layer, a plurality of sub-pixel isolation structures, and a plurality of black matrix structures disposed between the plurality of sub-pixel isolation structures and the transparent layer. The sub-pixel isolation structures define a plurality color conversion wells of plurality of sub-pixels. A color conversion material is disposed in the color conversion well. The plurality of black matrix structures define a plurality of color resist wells of the plurality of sub-pixels. A color resist is disposed in the color resist wells. The LED panel includes a plurality of micro-LEDs disposed on a backplane. The plurality of micro-LEDs correspond to a sub-pixel.

### CROSS-REFERENCE TO RELATED APPLICATIONS

This application claims priority to U.S. Provisional Application Ser. No. 63/381,423, filed Oct. 28, 2022, the contents of which are incorporated herein by reference in their entirety.

### BACKGROUND

### Field

Embodiments of the present disclosure generally relate to LED pixels and methods of fabricating LED pixels. In particular, the disclosure relates to quantum dot conversion layers and methods of fabrication.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

An LED panel that uses micron-scale LEDs based on III-V semiconductor technology (also called micro-LEDs) would have a variety of advantages as compared to OLEDs, e.g., higher energy efficiency, brightness, and lifetime, as well as fewer material layers in the display stack which can simplify manufacturing. However, there are challenges to fabrication of micro-LED panels. For instance, color purity of quantum dot (QD) color conversion materials is not ideal due to the broad band spectrum emission of the LED. In addition, polarizers that are integrated with QDs may reduce the brightness of the red/green/blue (RGB) transmission. These factors may compromise the quality of the display.

Therefore, what is needed in the art is a more efficient QD color conversion layer.

### SUMMARY

In one embodiment, a pixel is disclosed. The pixel includes a color panel, a light emitting diode (LED) panel, and an adhesive material disposed between the color panel and the LED panel. The color panel includes a transparent layer, a plurality of sub-pixel isolation structures, and a plurality of black matrix structures disposed between the plurality of sub-pixel isolation structures and the transparent layer. The plurality of sub-pixel isolation structures, define a plurality color conversion wells of a plurality of sub-pixels. The plurality of color conversion wells include a first color conversion well of a first sub-pixel, a second color conversion well of a second sub-pixel, and a third color conversion well of a third sub-pixel. A first color conversion material is disposed within the first color conversion well. A second color conversion material is disposed within the second color conversion well. A third color conversion material is disposed within the third color conversion well. The plurality of black matrix structures define a plurality of color resist wells of the plurality of sub-pixels. The plurality of color resist wells include a first color resist well of the first sub-pixel, a second color resist well of the second sub-pixel, and a third color resist well of the third sub-pixel. The light emitting diode (LED) panel includes a plurality of micro-LEDs disposed on a backplane. A first micro-LED of the plurality of micro-LEDs corresponds to the first sub-pixel. A second micro-LED of the plurality of micro-LEDs corresponds to the second sub-pixel. A third micro-LED of the plurality of micro-LEDs corresponds to the third sub-pixel.

In another embodiment, a pixel is disclosed. The pixel includes a color panel and a light emitting diode (LED) panel. The color panel includes a color resist transparent layer, a color conversion transparent layer, a plurality of sub-pixel isolation structures, a first adhesive material disposed between the color conversion transparent layer and the color resist transparent layer, and a plurality of black matrix structures disposed between the transparent layer and the sub-pixel isolation structures. The plurality of sub-pixel isolation structures define a plurality of color conversion wells of a plurality of sub-pixels. The plurality of color conversion wells include a first color conversion well of a first sub-pixel, a second color conversion well of a second sub-pixel, and a third color conversion well of a third sub-pixel. A first color conversion material is disposed within the first color conversion well. A second color conversion material is disposed within the second color conversion well. A third color conversion material is disposed within the third color conversion well. The plurality of black matrix structures define a plurality of color resist wells of the plurality of sub-pixels. The plurality of color resist wells include a first color resist well of the first sub-pixel, a second color resist well of the second sub-pixel, and a third color resist well of the third sub-pixel. The light emitting diode (LED) panel includes a plurality of micro-LEDs disposed on a backplane. A first micro-LED of the plurality of micro-LEDs corresponds to the first sub-pixel, a second micro-LED of the plurality of micro-LEDs corresponds to the second sub-pixel, a third micro-LED of the plurality of micro-LEDs corresponds to the third sub-pixel. A second adhesive material disposed between the LED panel and the color panel.

In yet another embodiment, a method of making a micro-LED device is disclosed. The method includes patterning a plurality of black matrix structures over a transparent layer; disposing a color resist in the plurality of color resist wells defined by the black matrix structures; disposing an isolation structure layer over the black matrix structures and the plurality of color resist wells; patterning the isolation structure layer to form the plurality of sub-pixel isolation structures; disposing a color conversion material in the plurality of color conversion wells to form a color panel, wherein the plurality of color conversion wells are defined by the plurality of sub-pixel isolation structures; and bonding the color panel to a light emitting diode (LED) panel, the LED panel comprising the plurality of micro-LEDs disposed over a backplane.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic, cross-sectional view of a pixel having a first arrangement, according to embodiments.

FIG. 2 illustrates a flow diagram of a first method of forming a pixel having a first arrangement, according to embodiments.

FIGS. 3A-3M illustrate schematic, cross-sectional views of a pixel during the method of forming a pixel having a first arrangement, according to embodiments.

FIG. 4 illustrates a flow diagram of a second method of forming a pixel having a first arrangement, according to embodiments.

FIGS. 5A-5H illustrate schematic, cross-sectional views of a pixel during the method 400 according to embodiments.

FIG. 6A illustrates a schematic, cross-sectional view of a pixel having a second arrangement, according to embodiments.

FIG. 6B illustrates a schematic, cross-sectional view of a pixel having a third arrangement, according to embodiments.

FIG. 7 illustrates a flow diagram of a first method of forming a pixel having a second arrangement, according to embodiments.

FIGS. 8A-8N illustrate schematic, cross-sectional views of a pixel during the first method of forming a pixel having a second arrangement, according to embodiments.

FIG. 9 illustrates a flow diagram of a second method of forming a pixel having a second arrangement, according to embodiments.

FIGS. 10A-10I illustrate schematic, cross-sectional views of a pixel during the second method of forming a pixel having a second arrangement, according to embodiments.

FIG. 11A illustrates a schematic, cross-sectional view of a pixel having a fourth arrangement, according to embodiments.

FIG. 11B illustrates a schematic, cross-sectional view of a pixel having a fifth arrangement, according to embodiments.

FIG. 12 illustrates a flow diagram of a method of forming a pixel having a fourth arrangement, according to embodiments.

FIGS. 13A-13G illustrate schematic, cross-sectional views of a pixel during the method of forming a pixel having a fourth arrangement, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to LED pixels and methods of fabricating LED pixels. In particular, the disclosure relates to quantum dot conversion layers and methods of fabrication.

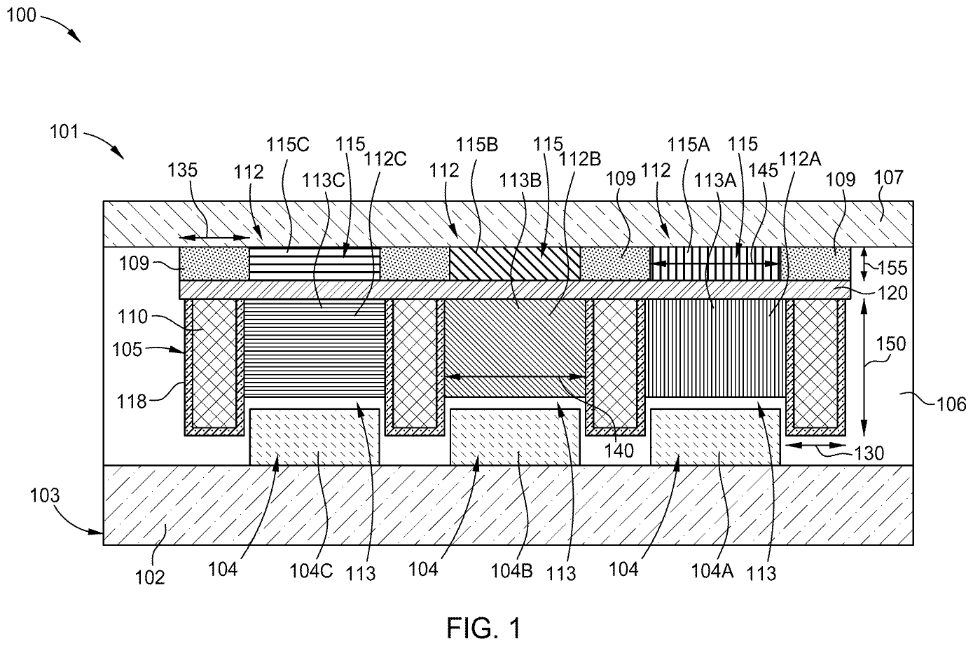

FIG. 1 illustrates a schematic, cross-sectional view of a pixel 100 having a first arrangement 101. The pixel 100 includes a LED panel 103 and a color panel 105. The LED panel 103 includes a plurality of micro-LEDs 104 disposed on a backplane 102. The micro-LEDs 104 are integrated with backplane circuitry so that each micro-LED 104 can be individually addressed. For example, the circuitry of the backplane 102 can include a TFT active matrix array with a thin-film transistor and a storage capacitor for each micro-LED 104, column address and row address lines, and column and row drivers, to drive the micro-LEDs 104. Alternatively, the micro-LEDs 104 can be driven by a passive matrix in the backplane circuitry. The backplane 102 can be fabricated using conventional CMOS processes.

An adhesive material 106 may be disposed between the LED panel 103 and the color panel 105. The adhesive material 106 may also be disposed between the micro-LEDs 104. The adhesive material 106 bonds the LED panel 103 to the color panel 105. The adhesive material 106 is disposed over, and in some embodiments directly on, the micro-LEDs 104. The adhesive material 106 includes an epoxy, acrylic, or urethane based clear adhesive, or a combination thereof.

The color panel 105 includes a transparent layer 107, a plurality of sub-pixel isolation (SI) structures 110, a capping layer 120, and a plurality of black matrix structures 109. The capping layer may include an indium-tin oxide (ITO), a silicon oxide (SiO₂), a silicon nitride (SiNₓ), silicon oxynitride (SiON), aluminum oxide (Al₂O₃), hafnium oxide (HfO₂), a tantalum oxide (Ta₂O₅), or a combination thereof. The adjacent sub-pixel isolation structures 110 define respective color conversion wells 113 of the plurality of sub-pixels 112. A color conversion material is disposed in the color conversion wells 113. The color conversion material includes a cadmium material, a zinc material, or an indium phosphide material or a combination thereof. A first color conversion material 113A is disposed in the color conversion well 113 of the first sub-pixel 112A, a second color conversion material 1136 is disposed in the color conversion well 113 of the second sub-pixel 112B, and a third color conversion material 113C is disposed in the color conversion well 113 of the third sub-pixel 112C. In some embodiments, the first sub-pixel 112A is a red sub-pixel and the first color conversion material 113A is a red color conversion material. In some embodiments, the second sub-pixel 112B is a green sub-pixel and the second color conversion material 1136 is a green color conversion material. In some embodiments, the third sub-pixel 112C is a blue sub-pixel and the third color conversion material 113C is a blue color conversion material.

When a micro-LED 104A of the red sub-pixel (e.g., first sub-pixel 112A) is turned on, the red color conversion material (e.g. first color conversion material 113A) will convert the light emitted from micro-LED 104A into red light. When a micro-LED 104B of the green sub-pixel (e.g., second sub-pixel 112B) is turned on, the green color conversion material (e.g. second color conversion material 1136) will convert the light emitted from micro-LED 104B into green light. When a micro-LED 104C of the blue sub-pixel (e.g., third sub-pixel 112C) is turned on, the blue color conversion material (e.g. third color conversion material 113C) will convert the light emitted from micro-LED 104C into blue light. In one embodiment, the pixel 100 includes a fourth sub-pixel. In some embodiments, a fourth sub-pixel does not include a color conversion material, i.e., color-conversion-layer-free. In other embodiments, the fourth sub-pixel includes a sacrificial material. In other embodiments, the at least three sub-pixels 112 include the same color conversion material. The fourth sub-pixel may be later filled with a color conversion material.

The sub-pixel isolation structures 110 include a photoresist material, such as an epoxy-based resist. The photoresist material may be a negative photoresist. The photo resist may be a black polymer structure, wherein the black polymer is opaque to UV light and visible light (e.g., the black polymer has high optical density or a white (e.g., light reflecting) polymer structure. The sub-pixel isolation structures 110 may have a width 130 of about 2 μm to about 20 μm. The sub-pixel isolation structures 110 may have a pitch 140 of about 10 μm to about 200 μm. The sub-pixel isolation structures 110 may have a height 150 of about 2 μm to about 30 μm, such as 5 μm to 15 μm. The sidewalls and top surface of the sub-pixel isolation structures 110 have a coating material 118 disposed thereon. The coating material 118 on the sub-pixel isolation structures 110 may provide for reflection of the emitted light to contain the converted light to the respective sub-pixel in order to collimate the light to the display. In some embodiments, the coating material 118 is a metal layer. The metal layer includes, but is not limited to, aluminum, silver, combinations thereof, or the like. In some embodiments, the coating material 118 may include a metal layer and a dielectric layer. The dielectric layer may include a silicon nitride (SiNₓ) material. The metal layer has a thickness of 100 nm to about 500 nm, and the dielectric layer has a thickness of about 100 nm to about 500 nm. In some embodiments, the coating layer could be an absorbing material. In yet other embodiments, the sub-pixel isolation structures 110 could have built in reflective properties.

The black matrix structures 109 define a respective color resist well 115 of the plurality of sub-pixels 112. A first color resist 115A is disposed in the well 115 of the first sub-pixel 112A, a second color resist 115B is disposed in the well 115 of the second sub-pixel 112B, and a third color resist 115C is disposed in the well 115 of the third sub-pixel 112C. In some embodiments, the first color resist 115A is a red color resist, the second color resist 115B is a green color resist, and the third color resist 115C is a blue color resist. The color resist is patterned by UV light. The color resist may serve as a color filter to improve display color quality.

The black matrix structures 109 include a black matrix material or a black resist material. The black matrix structures 109 may have a width 135 of about 2 μm to about 20 μm. The black matrix structures 109 may have a pitch 145 of about 2 μm to about 6 μm. The black matrix structures 109 may have a height 155 of about 1 μm to about 3 μm. The black matrix structures 109 reduce or eliminate the need for polarizers in the pixel 100. The black matrix structures 109 can reduce the thickness of the pixel 100. Further, the black matrix structures 109 reduce the reflection of the pixel 100 and improve the brightness of the pixel 100.

The capping layer 120 is disposed between the black matrix structures 109 and the sub-pixel isolation structures 110. The capping layer 120 is disposed over the sub-pixel isolation structures 110 and the color resist wells 115. The capping layer 120 isolates the color conversion wells 113 from the color resist wells 115. By isolating the color conversion wells 113 from the color resist wells 115, the capping layer prevents adverse reactions between the color conversion wells 113 from the color resist wells 115 in the event that the color conversion wells 113 from the color resist wells 115 are incompatible. The capping layer 120 has a thickness of about 100 nm to about 1 μm.

The transparent layer 107 is disposed over the black matrix structures 109 and the color resist wells 115. The transparent layer 107 includes a glass material, a polymethyl methacrylate (PMMA) material, or combination thereof. The structure of the pixel 100 with first arrangement 101 improves the color gamut, contrast, and uniformity of the pixel 100, while reducing or eliminating top-down cross-talk.

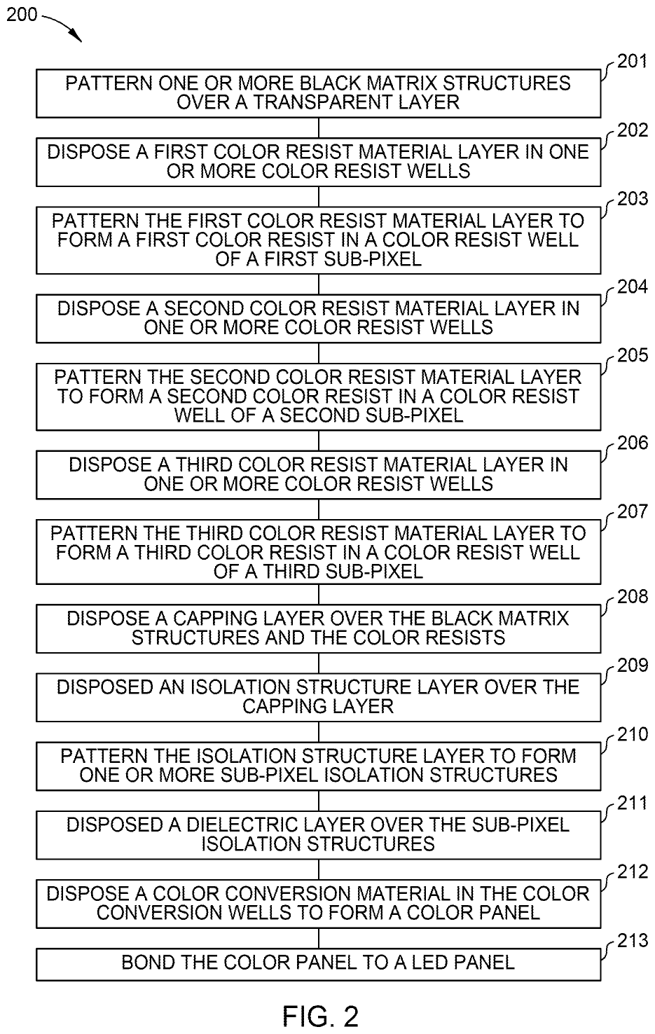

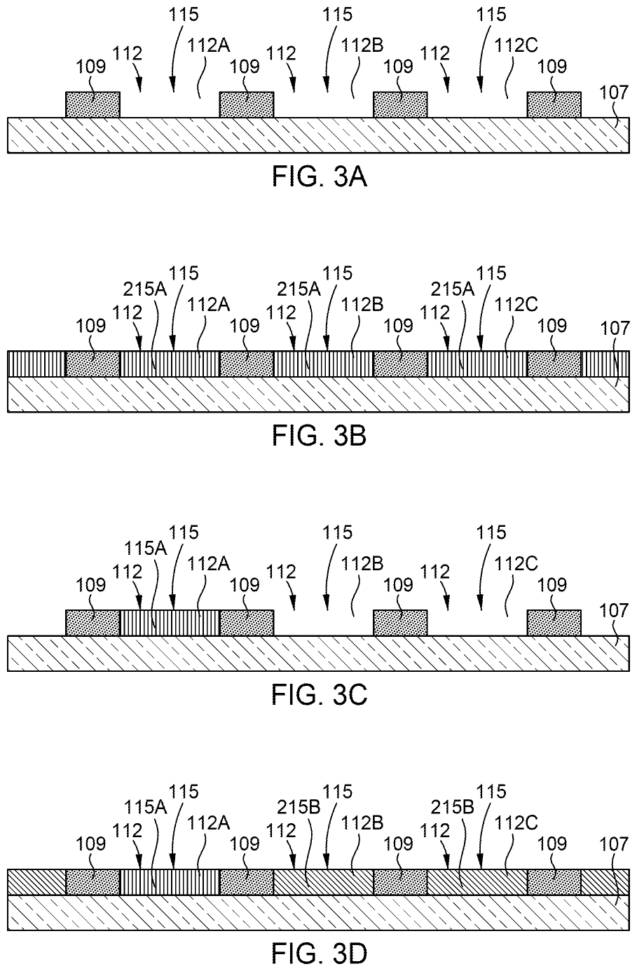

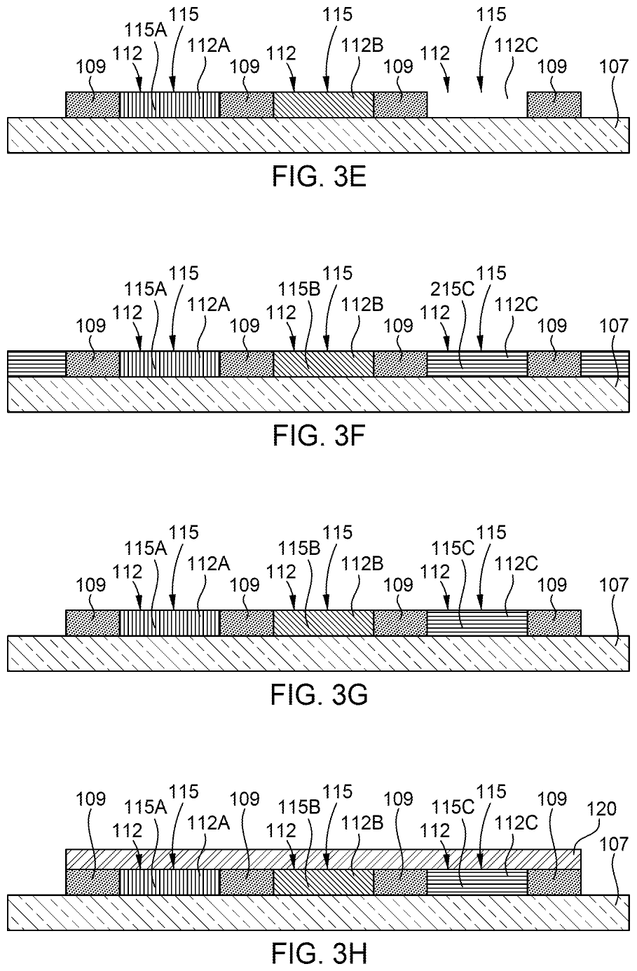

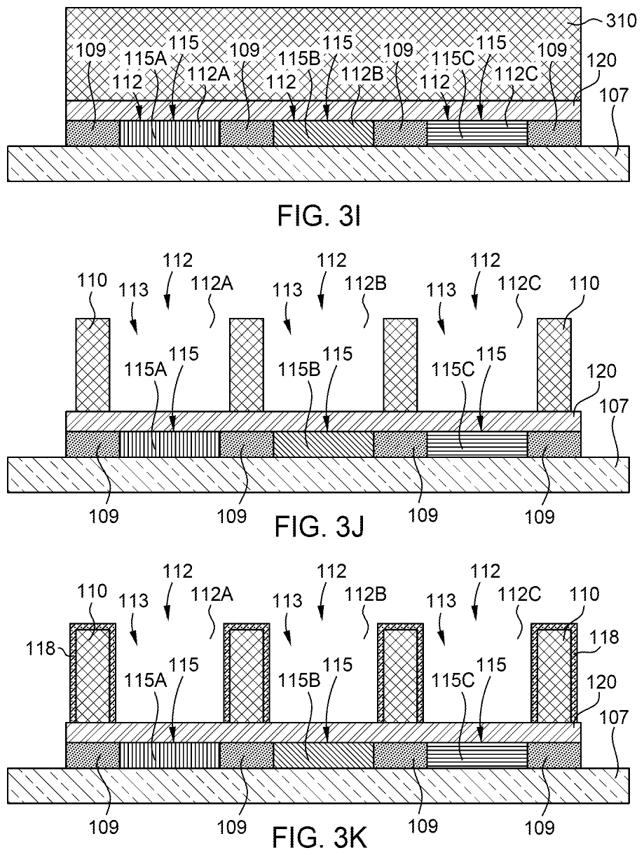

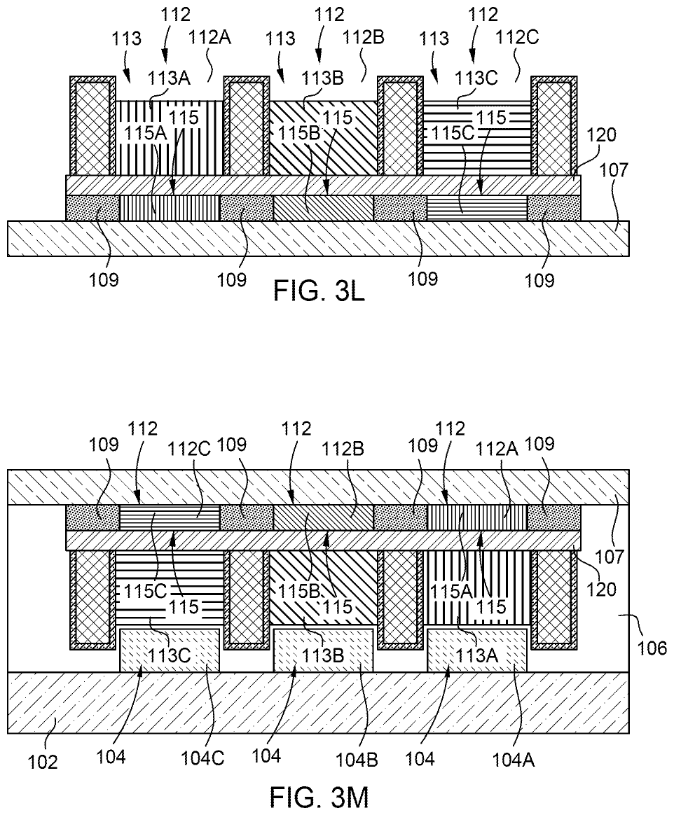

FIG. 2 illustrates a flow diagram of a first method 200 of forming a pixel 100 having a first arrangement 101. FIGS. 3A-3M illustrate schematic, cross-sectional views of a pixel 100 during the first method 200 of forming the pixel 100 having a first arrangement 101.

At operation 201, as shown in FIG. 3A, the plurality of black matrix structures 109 are patterned over a transparent layer 107. The black matrix structures 109 may be patterned by a lithographic process. The black matrix structures 109 define a plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C.

At operation 202, as shown in FIG. 3B, a first color resist material layer 215A is disposed in the plurality of color resist wells 115. The first color resist material layer 215A is disposed in the plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C. The first color resist material layer 215A may be disposed in the plurality of color resist wells 115 by a spin-coating process.

At operation 203, as shown in FIG. 3C, the first color resist material layer 215A is patterned to form a first color resist 115A in a color resist well 115 of a first sub-pixel 112A. The first color resist material layer 215A is patterned using a capillary force (CF) lithography process. The CF lithography process removes the first color resist material layer 215A from the color resist well 115 of the second sub-pixel 112B and the color resist well 115 of the third sub-pixel 112C.

At operation 204, as shown in FIG. 3D, a second color resist material layer 215B is disposed in the plurality of color resist wells 115. The second color resist material layer 215B is disposed in the plurality of color resist well 115, e.g. the color resist well 115 of a second sub-pixel 112B and the color resist well 115 of a third sub-pixel 112C. In some embodiments, the second color resist material layer 215B is not disposed in the color resist well 115 of the first sub-pixel 112A due to the first color resist 115A being disposed in the color resist well 115 of the first sub-pixel 112A. The second color resist material layer 2156 may be disposed in the plurality of color resist wells 115 by a spin-coating process.

At operation 205, as shown in FIG. 3E, the second color resist material layer 2156 is patterned to form a second color resist 1156 in a color resist well 115 of a second sub-pixel 1126. The second color resist material layer 215B is patterned using a capillary force (CF) lithography process. The CF lithography process removes the second color resist material layer 2156 from the color resist well 115 of the third sub-pixel 112C.

At operation 206, as shown in FIG. 3F, a third color resist material layer 215C is disposed in the plurality of color resist wells 115. The third color resist material layer 215C is disposed in the plurality of color resist wells 115, e.g. the color resist well 115 of the third sub-pixel 112C. In some embodiments, the third color resist material layer 215C is not disposed in the color resist well 115 of the first sub-pixel 112A or the color resist well 115 of the second sub-pixel 112B due to the first color resist 115A being disposed in the color resist well 115 of the first sub-pixel 112A and the second color resist 1156 being disposed in the color resist well 115 of the second sub-pixel 112B. The third color resist material layer 215C may be disposed in the plurality of color resist wells 115 by a spin-coating process.

At operation 207, as shown in FIG. 3G, the third color resist material layer 215C is patterned to form a third color resist 115C in a color resist well 115 of a third sub-pixel 112C. The third color resist material layer 215C is patterned using a capillary force (CF) lithography process.

At operation 208, as shown in FIG. 3H, a capping layer is disposed over the black matrix structures 109 and the color resists (e.g., the first color resist 115A, the second color resist 1156, and the third color resist 115C). The capping layer 120 is disposed over the black matrix structure 109 and the color resists using a physical vapor deposition (PVD) process, a chemical vapor deposition (CVD) process, or other deposition process.

At operation 209, as shown in FIG. 3I, a sub-pixel isolation structure layer 310 is disposed over the capping layer 120. The sub-pixel isolation structure layer 310 is disposed using a spin coating process.

At operation 210, as shown in FIG. 3J, the sub-pixel isolation structure layer 310 is patterned to form the plurality of sub-pixel isolation structures 110. The sub-pixel isolation structures 110 define the plurality of color conversion wells 113.

At operation 211, as shown in FIG. 3K, a coating material 118 is disposed over the sub-pixel isolation structures 110. The coating material 118 may include a metal layer and a dielectric layer. The metal layer may be deposited using a physical vapor deposition (PVD) process. The dielectric layer may be deposited using a chemical vapor deposition (CVD) or atomic layer deposition (ALD) process. The coating material 118 covers the top and sidewalls of the sub-pixel isolation structures 110.

At operation 212, as shown in FIG. 3L, a color conversion material is disposed in the color conversion wells 113 to form a color panel 105. A first color conversion material 113A is disposed in the color conversion well 113 of the first sub-pixel 112A, a second color conversion material 113B is disposed in the color conversion well 113 of the second sub-pixel 112B, and a third color conversion material 113C is disposed in the color conversion well 113 of the third sub-pixel 112C.

At operation 213, as shown in FIG. 3M, the color panel 105 is bonded to a LED panel 103. An adhesive material 106 bonds the color panel 105 to the LED panel 103. The LED panel 103 includes a backplane 102 and a plurality of micro-LEDs 104 disposed on the backplane 102. The plurality of micro-LEDs 104 may include a first micro-LED 104A corresponding to a first sub-pixel 112A, a second micro-LED 104B corresponding to a second sub-pixel 112B, and a third micro-LED 104C corresponding to a third sub-pixel 112C.

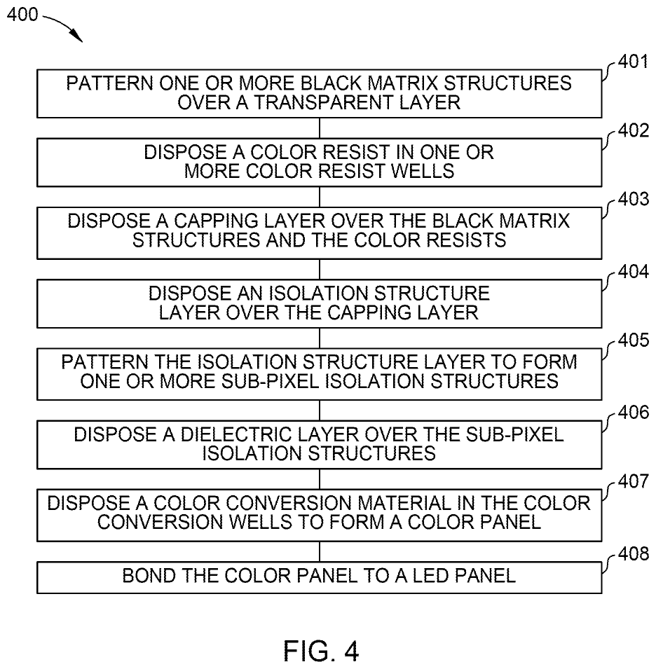

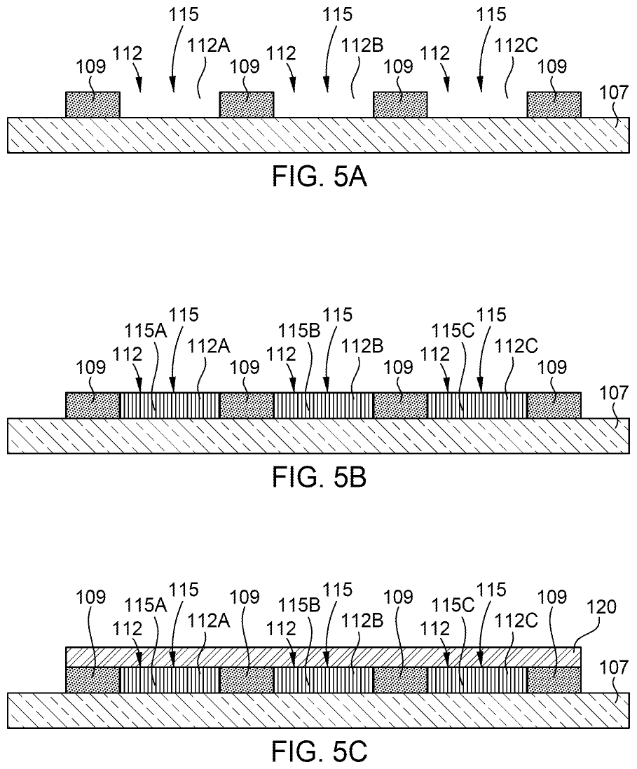

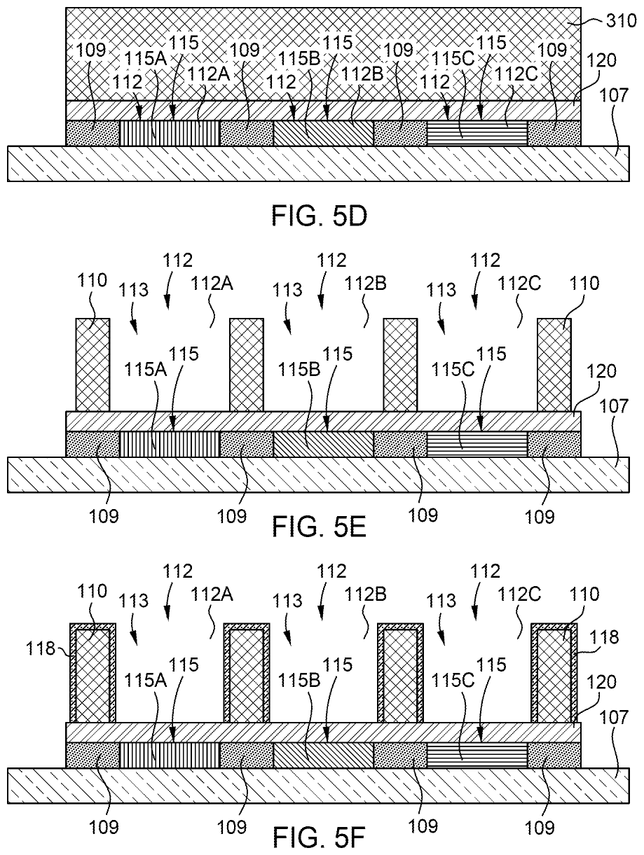

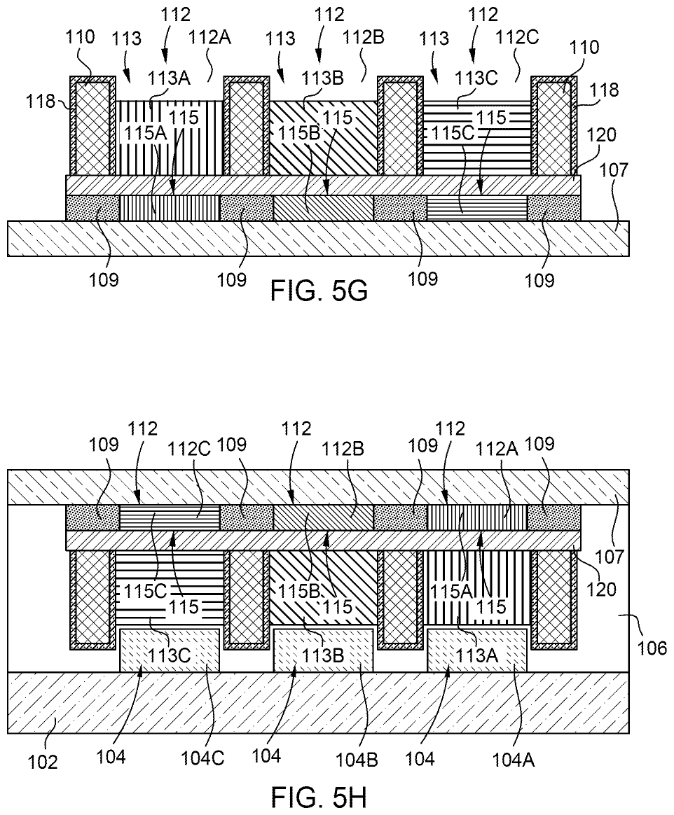

FIG. 4 illustrates a flow diagram of a second method 300 of forming a pixel 100 having a first arrangement 101. FIGS. 5A-5H illustrate schematic, cross-sectional views of a pixel 100 during the second method 300 of forming a pixel 100 having a first arrangement 101.

At operation 401, as shown in FIG. 5A, the plurality of black matrix structures 109 are patterned over a transparent layer 107. The black matrix structures 109 may be patterned by a lithography process. The black matrix structures 109 define a plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C.

At operation 402, as shown in FIG. 5B, a color resist is disposed in the plurality of color resist wells 115. A first color resist 115A is disposed in a color resist well 115 of a first sub-pixel 112A, a second color resist 115B is disposed in a color resist well 115 of a second sub-pixel 112B, and a third color resist 115C is disposed in a color resist well 115 of a third sub-pixel 112C. The color resist is disposed in the plurality of color resist wells 115 using an inkjet printing process.

At operation 403, as shown in FIG. 5C, a capping layer is disposed over the black matrix structures 109 and the color resists (e.g., the first color resist 115A, the second color resist 115B, and the third color resist 115C). The capping layer 120 is disposed over the black matrix structure 109 and the color resists using a physical vapor deposition (PVD) process, a chemical vapor deposition (CVD) process, or other deposition process.

At operation 404, as shown in FIG. 5D, a sub-pixel isolation structure layer 310 is disposed over the capping layer 120. The sub-pixel isolation structure layer 310 is disposed using a spin coating process.

At operation 405, as shown in FIG. 5E, the sub-pixel isolation structure layer 310 is patterned to form the plurality of sub-pixel isolation structures 110. The sub-pixel isolation structures 110 define the plurality of color conversion wells 113.

At operation 406 as shown in FIG. 5F, a coating material 118 is disposed over the sub-pixel isolation structures 110. The coating material 118 may include a metal layer and a dielectric layer. The metal layer may be deposited using a physical vapor deposition (PVD) process. The dielectric layer may be deposited using a chemical vapor deposition (CVD) or atomic layer deposition (ALD) process. The coating material 118 covers the top and sidewalls of the sub-pixel isolation structures 110.

At operation 407, as shown in FIG. 5G, a color conversion material is disposed in the color conversion wells 113 to form a color panel 105. A first color conversion material 113A is disposed in the color conversion well 113 of the first sub-pixel 112A, a second color conversion material 113B is disposed in the color conversion well 113 of the second sub-pixel 112B, and a third color conversion material 113C is disposed in the color conversion well 113 of the third sub-pixel 112C.

At operation 408, as shown in FIG. 5H, the color panel 105 is bonded to a LED panel 103. An adhesive material 106 bonds the color panel 105 to the LED panel 103. The LED panel 103 includes a backplane 102 and the plurality of micro-LEDs 104 disposed on the backplane 102. The plurality of micro-LEDs 104 may include a first micro-LED 104A corresponding to a first sub-pixel 112A, a second micro-LED 104B corresponding to a second sub-pixel 112B, and a third micro-LED 104C corresponding to a third sub-pixel 112C.

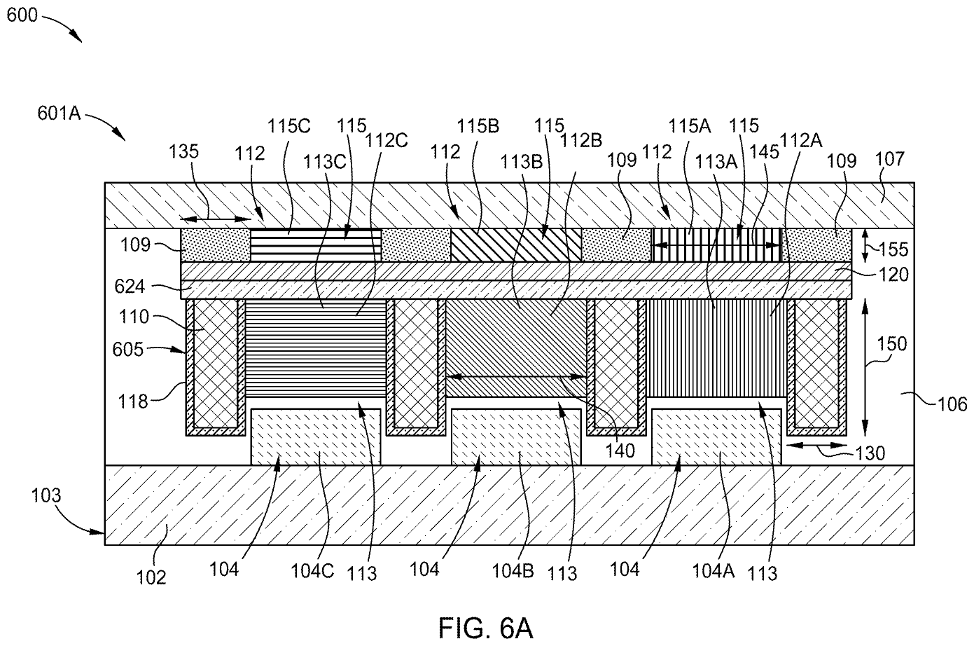

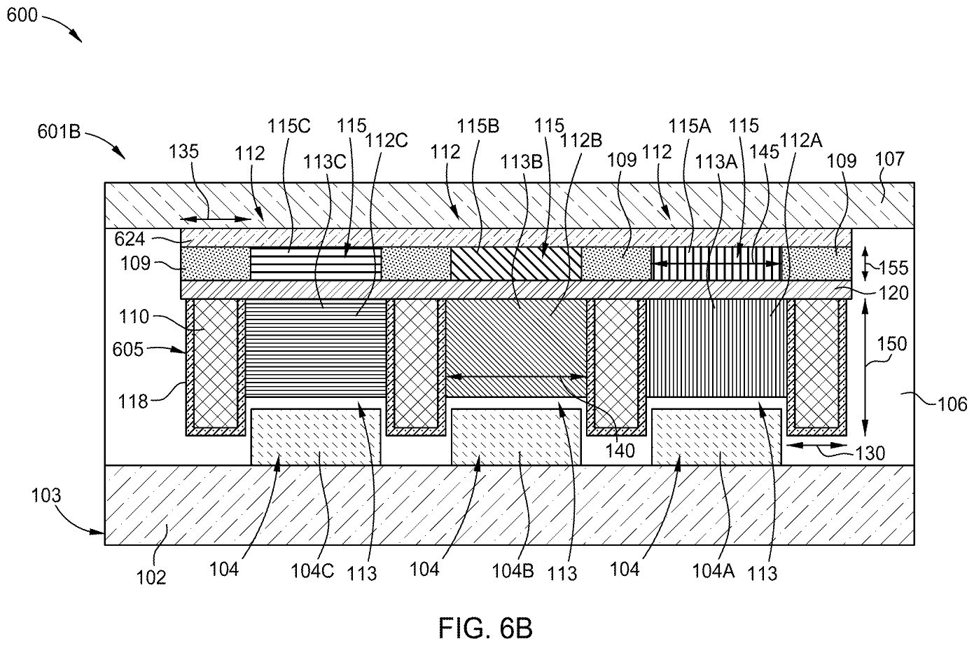

FIG. 6A illustrates a schematic, cross-sectional view of a pixel 600 having a second arrangement 600A. FIG. 6B illustrates a schematic, cross-sectional view of a pixel 600 having a third arrangement 600B.

The pixel 600 includes a LED panel 103 and a color panel 605. The LED panel includes the plurality of micro-LEDs 104 disposed on a backplane 102. The micro-LEDs 104 are integrated with backplane circuitry so that each micro-LED 104 can be individually addressed. For example, the circuitry of the backplane 102 can include a TFT active matrix array with a thin-film transistor and a storage capacitor for each micro-LED 104, column address and row address lines, and column and row drivers, to drive the micro-LEDs 104. Alternatively, the micro-LEDs 104 can be driven by a passive matrix in the backplane circuitry. The backplane 102 can be fabricated using conventional CMOS processes.

An adhesive material 106 may be disposed between the LED panel 103 and the color panel 605. The adhesive material 106 may also be disposed between the micro-LEDs 104. The adhesive material 106 bonds the LED panel 103 to the color panel 105. The adhesive material 106 is disposed over, and in some embodiments directly on, the micro-LEDs 104. The adhesive material 106 includes epoxy, acrylic, or urethane based clear adhesive, or a combination thereof.

The color panel 605 includes a transparent layer 107, the plurality of sub-pixel isolation (SI) structures 110, a capping layer, an ultraviolet (UV) blocking layer 624, and the plurality of black matrix structures 109. The adjacent sub-pixel isolation structures 110 define respective color conversion wells 113 of the plurality of sub-pixels 112. A color conversion material is disposed in the color conversion wells 113. The color conversion material includes a cadmium material, a zinc material, or an indium phosphide material or a combination thereof. A first color conversion material 113A is disposed in the color conversion well 113 of the first sub-pixel 112A, a second color conversion material 1136 is disposed in the color conversion well 113 of the second sub-pixel 1126, and a third sub-pixel 112C with a third color conversion material 113C is disposed in the color conversion well 113 of the third sub-pixel 112C. In some embodiments, the first sub-pixel 112A is a red sub-pixel and the first color conversion material 113A is a red color conversion material. In some embodiments, the second sub-pixel 1126 is a green sub-pixel and the second color conversion material 113B is a green color conversion material. In some embodiments, the third sub-pixel 112C is a blue sub-pixel and the third color conversion material 113C is a blue color conversion material.

When a micro-LED 104A of the first sub-pixel 112A is turned on, the red color conversion material (e.g. first color conversion material 113A) will convert the light emitted from micro-LED 104A into red light. When a micro-LED 104B of the second sub-pixel 112B is turned on, the green color conversion material (e.g. second color conversion material 1136) will convert the light emitted from micro-LED 104B into green light. When a micro-LED 104C of the blue sub-pixel (e.g., third sub-pixel 112C) is turned on, the blue color conversion material (e.g. third color conversion material 113C) will convert the light emitted from micro-LED 104C into blue light. In one embodiment, the pixel 600 includes a fourth sub-pixel. In some embodiments, a fourth sub-pixel does not include a color conversion material, i.e., color-conversion-layer-free. In other embodiments, the fourth sub-pixel includes a sacrificial material. In other embodiments, the at least three sub-pixels 112 include the same color conversion material. The fourth sub-pixel may be later filled with a color conversion material.

The sub-pixel isolation structures 110 include a photoresist material, such as an epoxy-based resist. The photoresist material may be a negative photoresist. The photo resist may be a black polymer structure, wherein the black polymer is opaque to UV light and visible light (e.g., the black polymer has high optical density or a white (e.g., light reflecting) polymer structure. The sub-pixel isolation structures 110 may have a width 130 of about 2 μm to about 20 μm. The sub-pixel isolation structures 110 may have a pitch 140 of about 10 μm to about 200 μm. The sub-pixel isolation structures 110 may have a height 150 of about 2 μm to about 30 μm, such as 5 μm to 15 μm. The sidewalls and top surface of the sub-pixel isolation structures 110 have a coating material 118 disposed thereon. The coating material 118 on the sub-pixel isolation structures 110 may provide for reflection of the emitted light to contain the converted light to the respective sub-pixel in order to collimate the light to the display. In some embodiments, the coating material 118 is a metal layer. The metal layer includes, but is not limited to, aluminum, silver, combinations thereof, or the like. In some embodiments, the coating material 118 may include a metal layer and a dielectric layer. The dielectric layer may include a silicon nitride (SiNₓ) material. The metal layer has a thickness of 100 nm to about 500 nm, and the dielectric layer has a thickness of about 100 nm to about 500 nm. In some embodiments, the coating layer could be an absorbing material. In yet other embodiments, the sub-pixel isolation structures 110 could have built in reflective properties.

The black matrix structures 109 define a respective color resist well 115 of the plurality of sub-pixels 112. A first color resist 115A is disposed in the well 115 of the first sub-pixel 112A, a second color resist 115B is disposed in the well 115 of the second sub-pixel 112B, and a third color resist 115C is disposed in the well 115 of the third sub-pixel 112C. In some embodiments, the first color resist 115A is a red color resist, the second color resist 115B is a green color resist, and the third color resist 115C is a blue color resist. The color resist is patterned by UV light. The color resist may serve as a color filter to improve display color quality.

The black matrix structures 109 include a black matrix material or a black resist material. The black matrix structures 109 may have a width 135 of about 2 μm to about 20 μm The black matrix structures 109 may have a pitch 145 of about 10 μm to about 200 μm. The black matrix structures 109 may have a height 155 of about 1 μm to about 3 μm. The black matrix structures 109 reduce or eliminate the need for polarizers in the pixel 600. The black matrix structures 109 can reduce the thickness of the pixel 600. Further, the black matrix structure 109 reduce the reflection of the pixel 600 and improve the brightness of the pixel 600.

In one embodiment, as shown in FIG. 6A, the capping layer 120 and UV blocking layer 624 are disposed between the black matrix structures 109 and the sub-pixel isolation structures 110. The UV blocking layer 624 is disposed over the sub-pixel isolation structure 110. The capping layer 120 is disposed over the UV blocking layer 624. The black matrix structures 109 are disposed over the capping layer 120.

In another embodiment, as shown in FIG. 6B, the capping layer 120 is disposed between the black matrix structures 109 and the sub-pixel isolation structures 110. The capping layer 120 is disposed over the sub-pixel isolation structures 110. The UV blocking layer 624 is disposed between the black matrix structure 109 and the transparent layer 107. The UV blocking layer 624 is disposed over the black matrix structures 109.

The capping layer 120 is disposed over the sub-pixel isolation structures 110 and the color resist wells 115. The capping layer 120 isolates the color conversion wells 113 from the color resist wells 115. The capping layer 120 has a thickness of about 100 nm to about 1 μm. The UV blocking layer 624 has a thickness of about 100 nm to about 1 μm.

The transparent layer 107 is disposed over the black matrix structures 109 and the color resist wells 115. The transparent layer 107 includes a glass material, a polymethyl methacrylate (PMMA) material, or combination thereof. The structure of the pixel 600 with second arrangement 601A and third arrangement 601B improves the color gamut, contrast, and uniformity of the pixel 600, while reducing or eliminating top-down cross-talk.

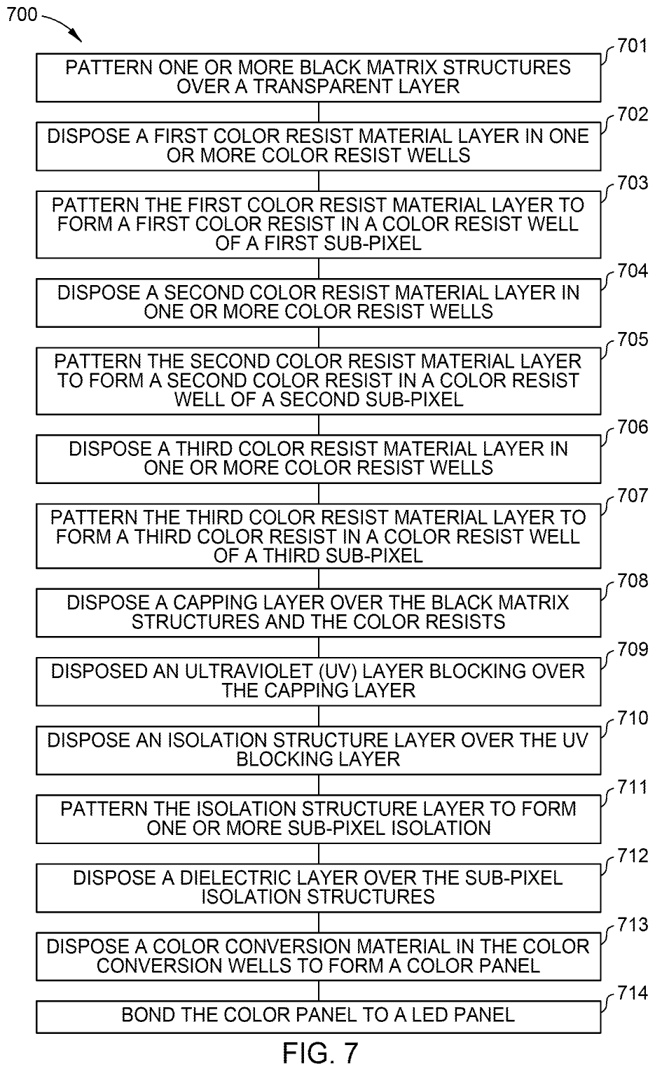

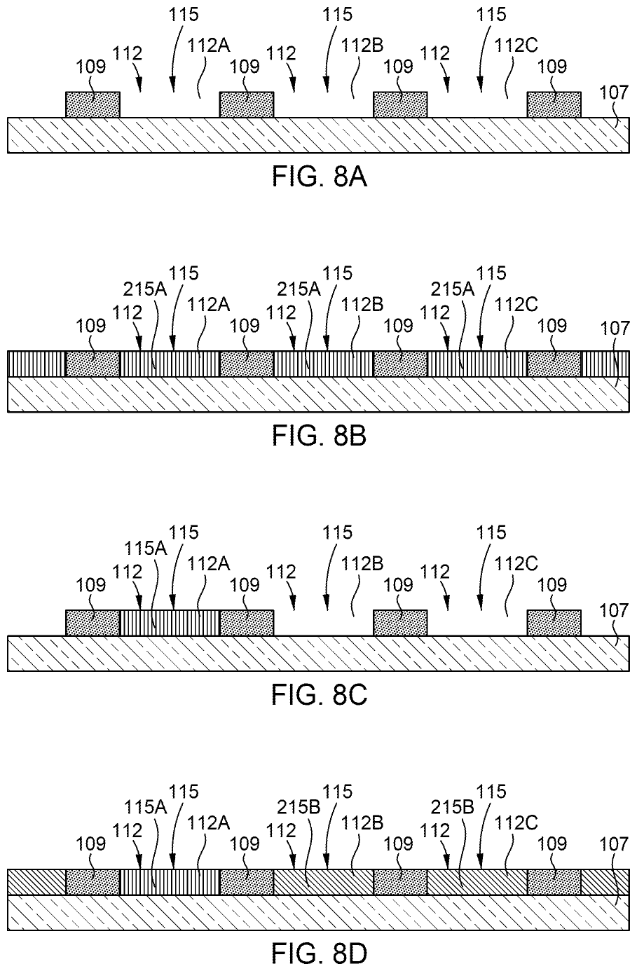

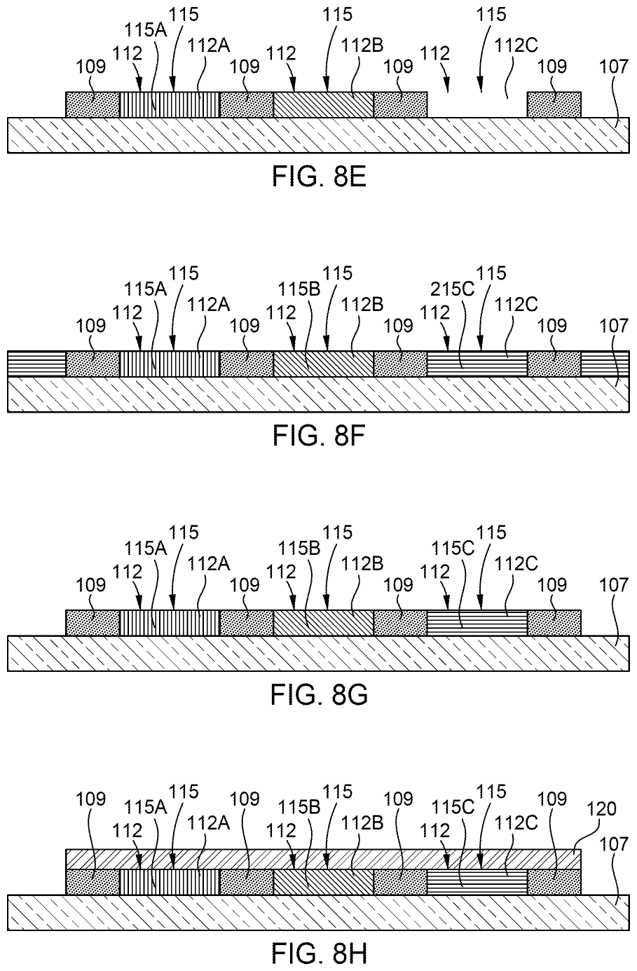

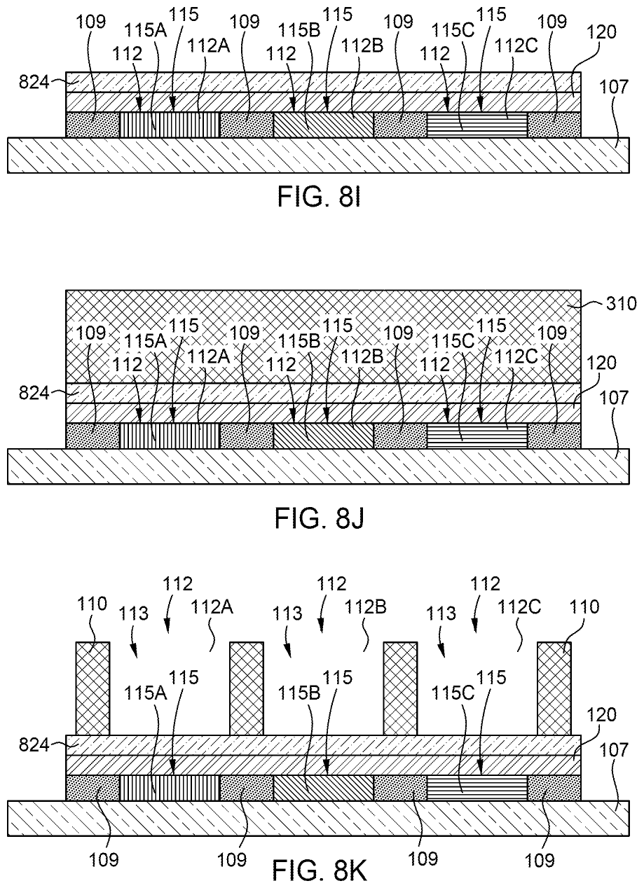

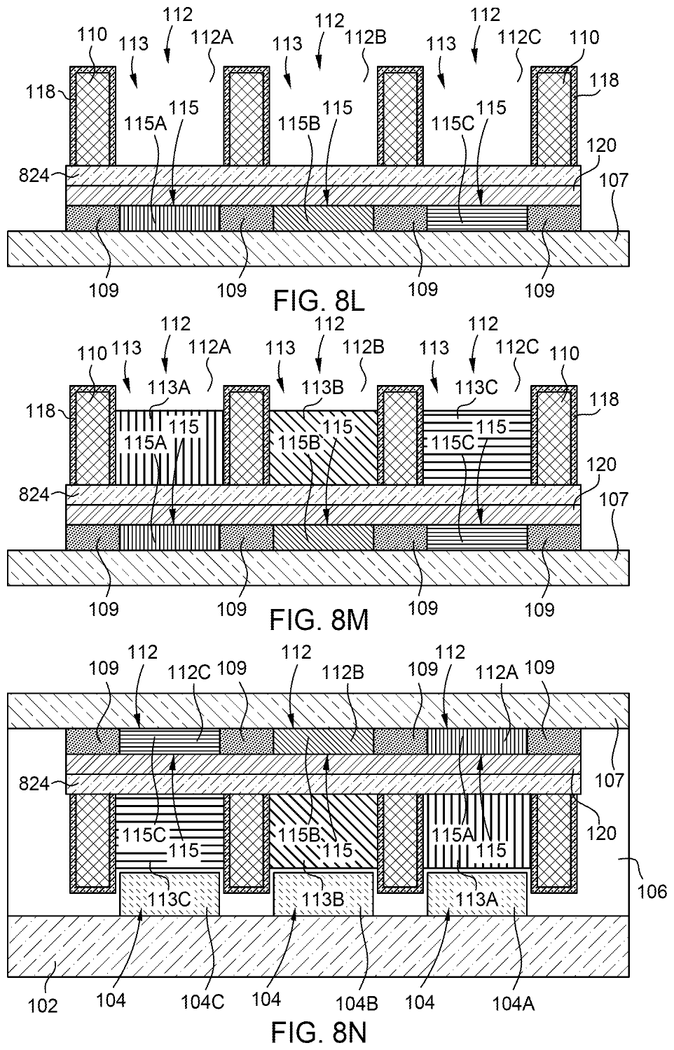

FIG. 7 illustrates a flow diagram of a first method 700 of forming a pixel 600 having a second arrangement 601A. FIGS. 8A-8N illustrate schematic, cross-sectional views of a pixel 600 during the first method 700 of forming a pixel 600 having a second arrangement 600A.

At operation 701, as shown in FIG. 8A, the plurality of black matrix structures 109 are patterned over a transparent layer 107. The black matrix structures 109 may be patterned by a lithography process. The black matrix structures 109 define the plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C.

At operation 702, as shown in FIG. 8B, a first color resist material layer 215A is disposed in the plurality of color resist wells 115. The first color resist material layer 215A is disposed in the plurality of color resist well 115, e.g. a color resist well 115 of a first sub-pixel 112A, a color resist well 115 of a second sub-pixel 112B, and a color resist well 115 of a third sub-pixel 112C. The first color resist material layer 215A may be disposed in the plurality of color resist wells 115 by a spin-coating process.

At operation 703, as shown in FIG. 8C, the first color resist material layer 215A is patterned to form a first color resist 115A in a color resist well 115 of a first sub-pixel 112A. The first color resist material layer 215A is patterned using a capillary force (CF) lithography process. The CF lithography process removes the first color resist material layer 215A from the color resist well 115 of the second sub-pixel 112B and the color resist well 115 of the third sub-pixel 112C.

At operation 704, as shown in FIG. 8D, a second color resist material layer 2156 is disposed in the plurality of color resist wells 115. The second color resist material layer 215B is disposed in the plurality of color resist well 115, e.g. the color resist well 115 of a second sub-pixel 112B and the color resist well 115 of a third sub-pixel 112C. In some embodiments, the second color resist material layer 2156 is not disposed in the color resist well 115 of the first sub-pixel 112A due to the first color resist 115A being disposed in the color resist well 115 of the first sub-pixel 112A. The second color resist material layer 2156 may be disposed in the plurality of color resist wells 115 by a spin-coating process.

At operation 705, as shown in FIG. 8E, the second color resist material layer 2156 is patterned to form a second color resist 1156 in a color resist well 115 of a second sub-pixel 1126. The second color resist material layer 215B is patterned using a capillary force (CF) lithography process. The CF lithography process removes the second color resist material layer 2156 from the color resist well 115 of the third sub-pixel 112C.

At operation 706, as shown in FIG. 8F, a third color resist material layer 215C is disposed in the plurality of color resist wells 115. The third color resist material layer 215C is disposed in the plurality of color resist well 115, e.g. the color resist well 115 of the third sub-pixel 112C. In some embodiments, the third color resist material layer 215C is not disposed in the color resist well 115 of the first sub-pixel 112A or the color resist well 115 of the second sub-pixel 112B due to the first color resist 115A being disposed in the color resist well 115 of the first sub-pixel 112A and the second color resist 1156 being disposed in the color resist well 115 of the second sub-pixel 112B. The third color resist material layer 215C may be disposed in the plurality of color resist wells 115 by a spin-coating process.

At operation 707, as shown in FIG. 8G, the third color resist material layer 215C is patterned to form a third color resist 115C in a color resist well 115 of a third sub-pixel 112C. The third color resist material layer 215C is patterned using a capillary force (CF) lithography process.

At operation 708, as shown in FIG. 8H, a capping layer is disposed over the black matrix structures 109 and the color resists (e.g., the first color resist 115A, the second color resist 1156, and the third color resist 115C). The capping layer 120 is disposed over the black matrix structure 109 and the color resists using a physical vapor deposition (PVD) process, a chemical vapor deposition (CVD) process, or other deposition process.

At operation 709, as shown in FIG. 8I, an ultraviolet (UV) blocking layer 624 is disposed over the capping layer 120. The UV blocking layer is disposed using a chemical vapor deposition (CVD) process, an atomic layer deposition (ALD) process, or a spin coating process.

At operation 710, as shown in FIG. 8J, a sub-pixel isolation structure layer 310 is disposed over the capping layer 120. The sub-pixel isolation structure layer 310 is disposed using a spin coating process.

At operation 711, as shown in FIG. 8K, the sub-pixel isolation structure layer 310 is patterned to form the plurality of sub-pixel isolation structures 110 and the plurality of color conversion wells 113. The sub-pixel isolation structures 110 define the plurality of color conversion wells 113.

At operation 712, as shown in FIG. 8L, a coating material 118 is disposed over the sub-pixel isolation structures 110. The coating material 118 may include a metal layer and a dielectric layer. The metal layer may be deposited using a physical vapor deposition (PVD) process. The dielectric layer may be deposited using a chemical vapor deposition (CVD) or atomic layer deposition (ALD) process. The coating material 118 covers the top and sidewalls of the sub-pixel isolation structures 110.

At operation 713, as shown in FIG. 8M, a color conversion material is disposed in the color conversion wells 113 to form a color panel 605. A first color conversion material 113A is disposed in the color conversion well 113 of the first sub-pixel 112A, a second color conversion material 113B is disposed in the color conversion well 113 of the second sub-pixel 112B, and a third color conversion material 113C is disposed in the color conversion well 113 of the third sub-pixel 112C.

At operation 714, as shown in FIG. 8N, the color panel 605 is bonded to a LED panel 103. An adhesive material 106 bonds the color panel 605 to the LED panel 103. The LED panel 103 includes a backplane 102 and the plurality of micro-LEDs 104 disposed on the backplane 102. The plurality of micro-LEDs 104 may include a first micro-LED 104A corresponding to a first sub-pixel 112A, a second micro-LED 104B corresponding to a second sub-pixel 112B, and a third micro-LED 104C corresponding to a third sub-pixel 112C.

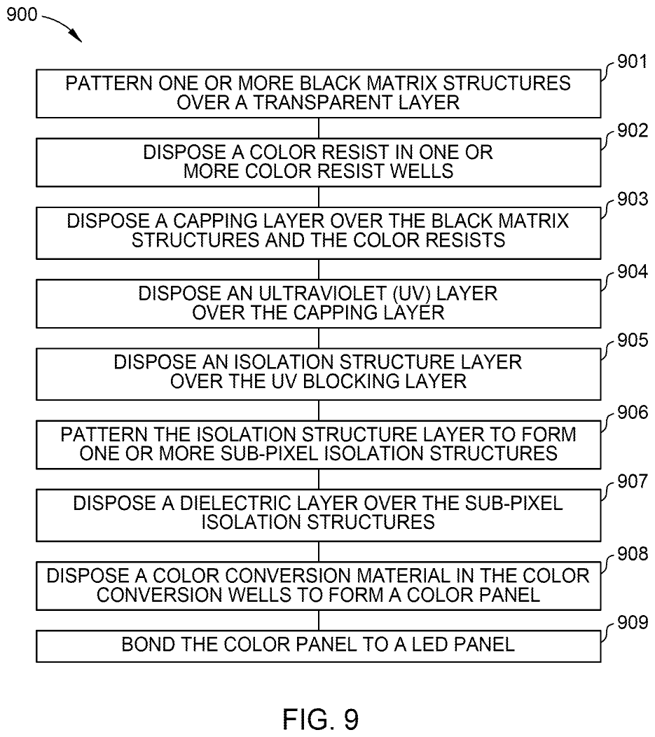

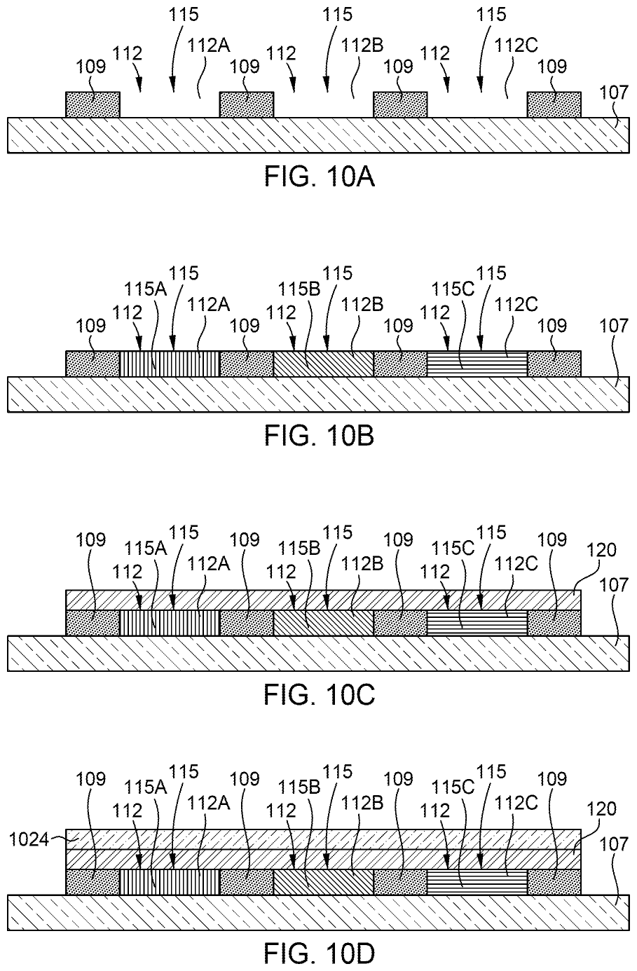

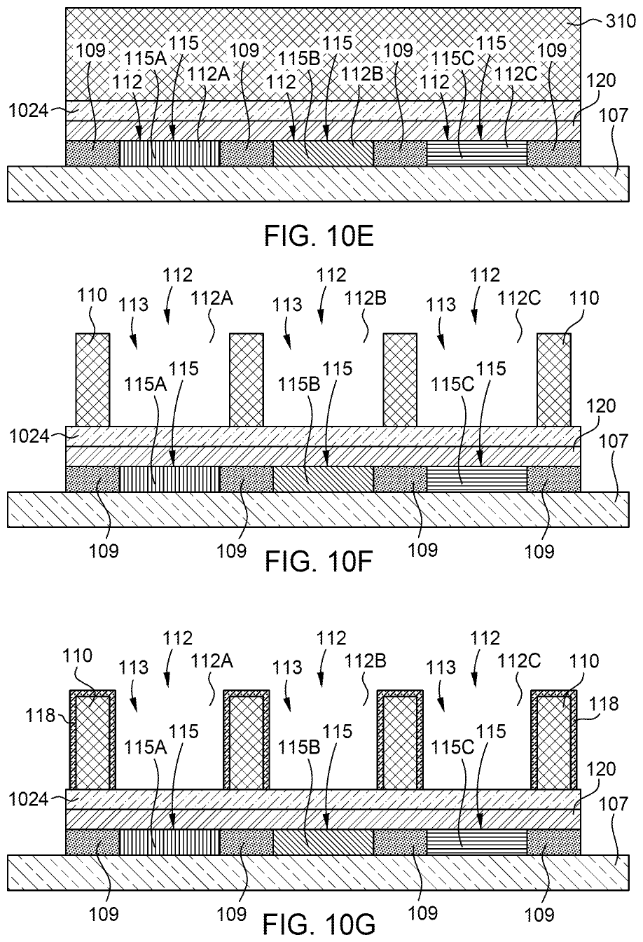

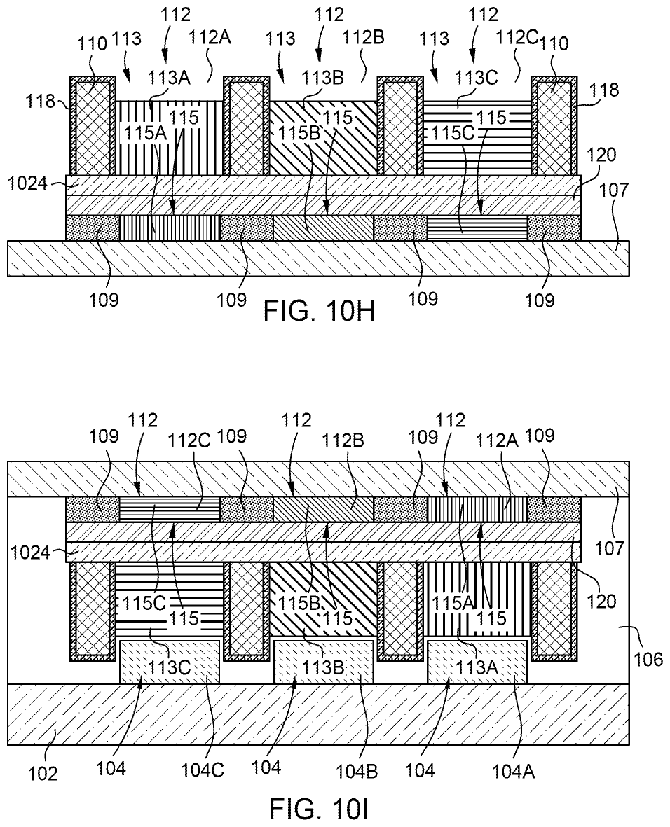

FIG. 9 illustrates a flow diagram of a second method 900 of forming a pixel 600 having a second arrangement 601A. FIGS. 10A-10I illustrate schematic, cross-sectional views of a pixel 600 during the second method 900 of forming the pixel 600 having a second arrangement 601A.

At operation 901, as shown in FIG. 10A, the plurality of black matrix structures 109 are patterned over a transparent layer 107. The black matrix structures 109 may be patterned by a lithography process. The black matrix structures 109 define the plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C.

At operation 902, as shown in FIG. 10B, a color resist is disposed in the plurality of color resist wells 115. A first color resist 115A is disposed in a color resist well 115 of a first sub-pixel 112A, a second color resist 115B is disposed in a color resist well 115 of a second sub-pixel 112B, and a third color resist 115C is disposed in a color resist well 115 of a third sub-pixel 112C. The color resists are disposed using an inkjet printing process.

At operation 903, as shown in FIG. 10C, a capping layer is disposed over the black matrix structures 109 and the color resists (e.g., the first color resist 115A, the second color resist 115B, and the third color resist 115C). The capping layer 120 is disposed over the black matrix structure 109 and the color resists using a physical vapor deposition (PVD) process, a chemical vapor deposition (CVD) process, or other deposition process.

At operation 904, as shown in FIG. 10D, an ultraviolet (UV) blocking layer 624 is disposed over the capping layer 120. The UV blocking layer is disposed using a chemical vapor deposition (CVD) process, an atomic layer deposition (ALD) process, or a spin coating process.

At operation 905, as shown in FIG. 10E, a sub-pixel isolation structure layer 310 is disposed over the capping layer 120. The sub-pixel isolation structure layer 310 is disposed using a spin coating process.

At operation 906, as shown in FIG. 10F, the sub-pixel isolation structure layer 310 is patterned to form the plurality of sub-pixel isolation structures 110. The sub-pixel isolation structures 110 define the plurality of color conversion wells 113.

At operation 907 as shown in FIG. 10G, a coating material 118 is disposed over the sub-pixel isolation structures 110. The coating material 118 may include a metal layer and a dielectric layer. The metal layer may be deposited using a physical vapor deposition (PVD) process. The dielectric layer may be deposited using a chemical vapor deposition (CVD) or atomic layer deposition (ALD) process. The coating material 118 covers the top and sidewalls of the sub-pixel isolation structures 110.

At operation 908, as shown in FIG. 10H, a color conversion material is disposed in the color conversion wells 113 to form a color panel 605. A first color conversion material 113A is disposed in the color conversion well 113 of the first sub-pixel 112A, a second color conversion material 113B is disposed in the color conversion well 113 of the second sub-pixel 112B, and a third color conversion material 113C is disposed in the color conversion well 113 of the third sub-pixel 112C.

At operation 909, as shown in FIG. 10I, the color panel 605 is bonded to a LED panel 103. An adhesive material 106 bonds the color panel 605 to the LED panel 103. The LED panel 103 includes a backplane 102 and the plurality of micro-LEDs 104 disposed on the backplane 102. The plurality of micro-LEDs 104 may include a first micro-LED 104A corresponding to a first sub-pixel 112A, a second micro-LED 104B corresponding to a second sub-pixel 112B, and a third micro-LED 104C corresponding to a third sub-pixel 112C.

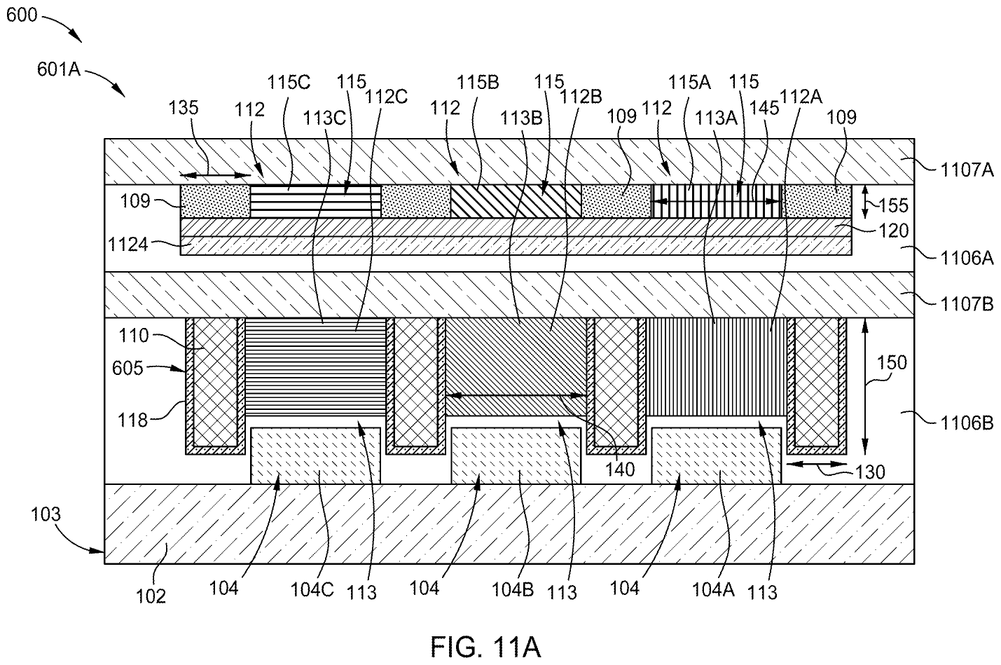

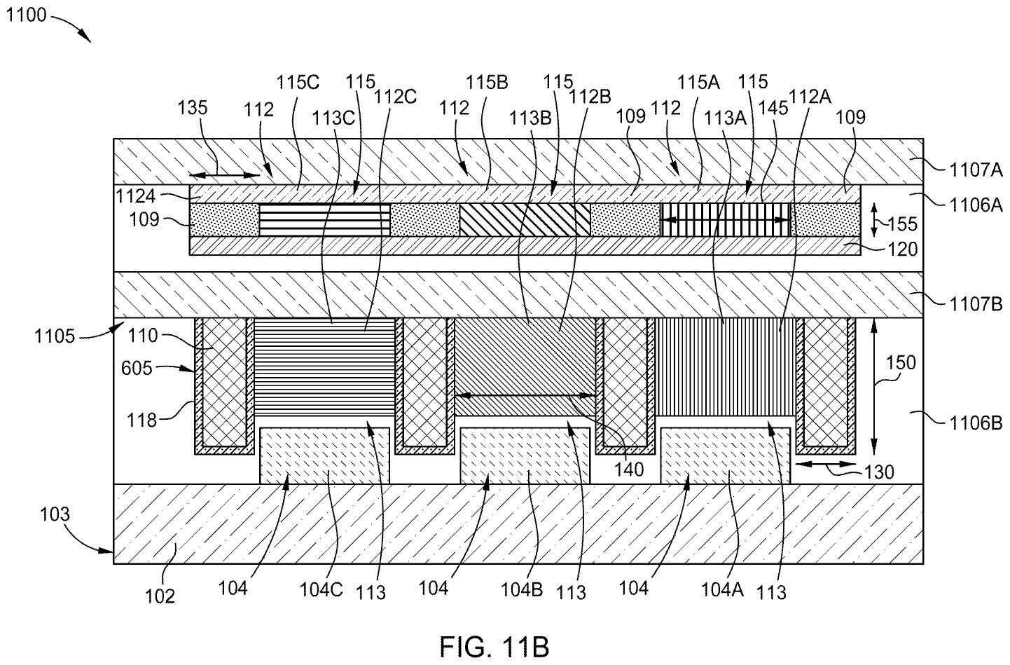

FIG. 11A illustrates a schematic, cross-sectional view of a pixel 1100 having a fourth arrangement 1101A. FIG. 11B illustrates a schematic, cross-sectional view of a pixel 1100 having a fifth arrangement 1101B.

The pixel 1100 includes a LED panel 103 and a color panel 1105. The LED panel includes the plurality of micro-LEDs 104 disposed on a backplane 102. The micro-LEDs 104 are integrated with backplane circuitry so that each micro-LED 104 can be individually addressed. For example, the circuitry of the backplane 102 can include a TFT active matrix array with a thin-film transistor and a storage capacitor for each micro-LED 104, column address and row address lines, and column and row drivers, to drive the micro-LEDs 104. Alternatively, the micro-LEDs 104 can be driven by a passive matrix in the backplane circuitry. The backplane 102 can be fabricated using conventional CMOS processes.

A second adhesive material 1106B may be disposed between the LED panel 103 and the color panel 1105. The second adhesive material 1106B may also be disposed between the micro-LEDs 104. The second adhesive material 1106B is disposed over, and in some embodiments directly on, the micro-LEDs 104. The second adhesive material 1106B bonds the LED panel 103 to the color panel 1105. The second adhesive material 1106B includes an epoxy, acrylic, or urethane based clear adhesive, or a combination thereof.

The color panel 1105 includes a color resist transparent layer 1107A, a color conversion transparent layer 11076, a first adhesive material 1106A, the plurality of sub-pixel isolation (SI) structures 110, a capping layer, an ultraviolet (UV) blocking layer 1124, and the plurality of black matrix structures 109. The adjacent sub-pixel isolation structures 110 define respective color conversion wells 113 of the plurality of sub-pixels 112. The color conversion material is disposed in the color conversion wells 113. The color conversion material includes a cadmium material, a zinc material, or an indium phosphide material or a combination thereof. A first color conversion material 113A is disposed in the color conversion well 113 of the first sub-pixel 112A, a second color conversion material 1136 is disposed in the color conversion well 113 of the second sub-pixel 1126, and a third color conversion material 113C is disposed in the color conversion well 113 of the third sub-pixel 112C. In some embodiments, the first sub-pixel 112A is a red sub-pixel and the first color conversion material 113A is a red color conversion material. In some embodiments, the second sub-pixel 1126 is a green sub-pixel and the second color conversion material 1136 is a green color conversion material. In some embodiments, the third sub-pixel 112C is a blue sub-pixel and the third color conversion material 113C is a blue color conversion material.

When a micro-LED 104A of the first sub-pixel 112A is turned on, the red color conversion material (e.g. first color conversion material 113A) will convert the light emitted from micro-LED 104A into red light. When a micro-LED 104B of the second sub-pixel 112B is turned on, the green color conversion material (e.g. second color conversion material 1136) will convert the light emitted from micro-LED 104B into green light. When a micro-LED 104C of the blue sub-pixel (e.g., third sub-pixel 112C) is turned on, the blue color conversion material (e.g. third color conversion material 113C) will convert the light emitted from micro-LED 104C into blue light. In one embodiment, the pixel 1100 includes a fourth sub-pixel. In some embodiments, a fourth sub-pixel does not include a color conversion material, i.e., color-conversion-layer-free. In other embodiments, the fourth sub-pixel includes a sacrificial material. In other embodiments, the at least three sub-pixels 112 include the same color conversion material. The fourth sub-pixel may be later filled with a color conversion material.

The sub-pixel isolation structures 110 include a photoresist material, such as an epoxy-based resist. The photoresist material may be a negative photoresist. The photo resist may be a black polymer structure, wherein the black polymer is opaque to UV light and visible light (e.g., the black polymer has high optical density or a white (e.g., light reflecting) polymer structure. The sub-pixel isolation structures 110 may have a width 130 of about 2 μm to about 20 μm. The sub-pixel isolation structures 110 may have a pitch 140 of about 10 μm to about 200 μm. The sub-pixel isolation structures 110 may have a height 150 of about 2 μm to about 30 μm, such as 5 μm to 15 μm. The sidewalls and top surface of the sub-pixel isolation structures 110 have a coating material 118 disposed thereon. The coating material 118 on the sub-pixel isolation structures 110 may provide for reflection of the emitted light to contain the converted light to the respective sub-pixel in order to collimate the light to the display. In some embodiments, the coating material 118 is a metal layer. The metal layer includes, but is not limited to, aluminum, silver, combinations thereof, or the like. In some embodiments, the coating material 118 may include a metal layer and a dielectric layer. The dielectric layer may include a silicon nitride (SiNₓ) material. The metal layer has a thickness of 100 nm to about 500 nm, and the dielectric layer has a thickness of about 100 nm to about 500 nm. In some embodiments, the coating layer could be an absorbing material. In yet other embodiments, the sub-pixel isolation structures 110 could have built in reflective properties.

The black matrix structures 109 define a respective color resist well 115 of the plurality of sub-pixels 112. A first color resist 115A is disposed in the well 115 of the first sub-pixel 112A, a second color resist 1158 is disposed in the well 115 of the second sub-pixel 112B, and a third color resist 115C is disposed in the well 115 of the third sub-pixel 112C. In some embodiments, the first color resist 115A is a red color resist, the second color resist 1158 is a green color resist, and the third color resist 115C is a blue color resist. The color resist is patterned by UV light. The color resist may serve as a color filter to improve display color quality.

The black matrix structures 109 include a black matrix material or a black resist material. The black matrix structures 109 may have a width 135 of about 2 μm to about 20 μm. The black matrix structures 109 may have a pitch 145 of about 10 μm to about 40 μm. The black matrix structures 109 may have a height 155 of about 1 μm to 3 μm. The black matrix structures 109 reduce or eliminate the need for polarizers in the pixel 1100. The black matrix structure 109 can reduce the thickness of the pixel 1100. Further, the black matrix structure 109 reduce the reflection of the pixel 1100 and improve the brightness of the pixel 1100.

In one embodiment, as shown in FIG. 11A, the color conversion transparent layer 1107B, the first adhesive material 1106A, and the UV blocking 1124 layer are disposed between the sub-pixel isolation structures 110 and the capping layer 120. The color conversion transparent layer 1107B is disposed over the sub-pixel isolation structures 110. The first adhesive material 1106A is disposed over the color conversion transparent layer 1107B. The UV blocking layer 1124 is disposed over the first adhesive material 1106A. The first adhesive material 1106A may be disposed between a portion of the color resist transparent layer 1107A and the color conversion transparent layer 1107B, e.g., the first adhesive material 1106A is disposed over the color conversion transparent layer 1107B, the sides of the UV blocking layer 1124, the sides of the capping layer 120, and the sides of the outermost black matrix structures 109.

In another embodiment, as shown in FIG. 11B, the color conversion transparent layer 1107B and the first adhesive material 1106A are disposed between the sub-pixel isolation structures 110 and the capping layer 120. The UV blocking layer 1124 is disposed between the black matrix structures 109 and the color resist transparent layer 1107A. The color conversion transparent layer 1107B is disposed over the sub-pixel isolation structures 110. The first adhesive material 1106A is disposed over the color conversion transparent layer 1107B. The capping layer 120 is disposed over the first adhesive material 1106A. The first adhesive material 1106A may be disposed between a portion of the color resist transparent layer 1107A and the color conversion transparent layer 1107B, e.g., the first adhesive material 1106A is disposed over the color conversion transparent layer 1107B, the sides of the UV blocking layer 1124, the sides of the capping layer 120, and the sides of the outermost black matrix structures 109.

The capping layer 120 is disposed over the sub-pixel isolation structures 110 and the color resist wells 115. The capping layer 120 isolates the color conversion wells 113 from the color resist wells 115. The capping layer 120 has a thickness of about 100 nm to about 1 μm. The UV blocking 1124 layer has a thickness of about 100 nm to about 1 μm. The first adhesive material 1106A includes an epoxy, acrylic, or urethane based clear adhesive, or a combination thereof.

The color resist transparent layer 1107A and the color conversion transparent layer 1107B are disposed over sub-pixel isolation structure 110 and the black matrix structures 109, respectively. The color resist transparent layer 1107A and the color conversion transparent layer 1107B include a glass material, a polymethyl methacrylate (PMMA) material, or combination thereof. The structure of the pixel 1100 with fourth arrangement 1101A and fifth arrangement 11016 improves the color gamut, contract, and uniformity of the pixel 1100, while reducing or eliminating top-down cross-talk.

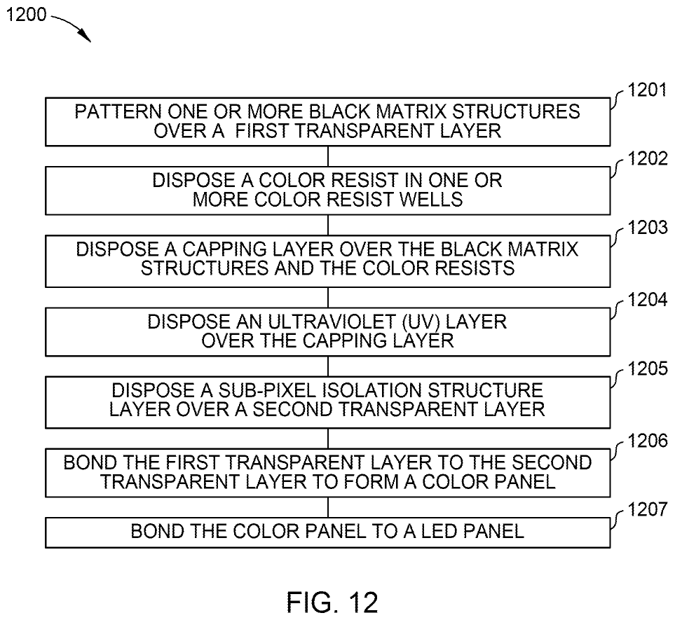

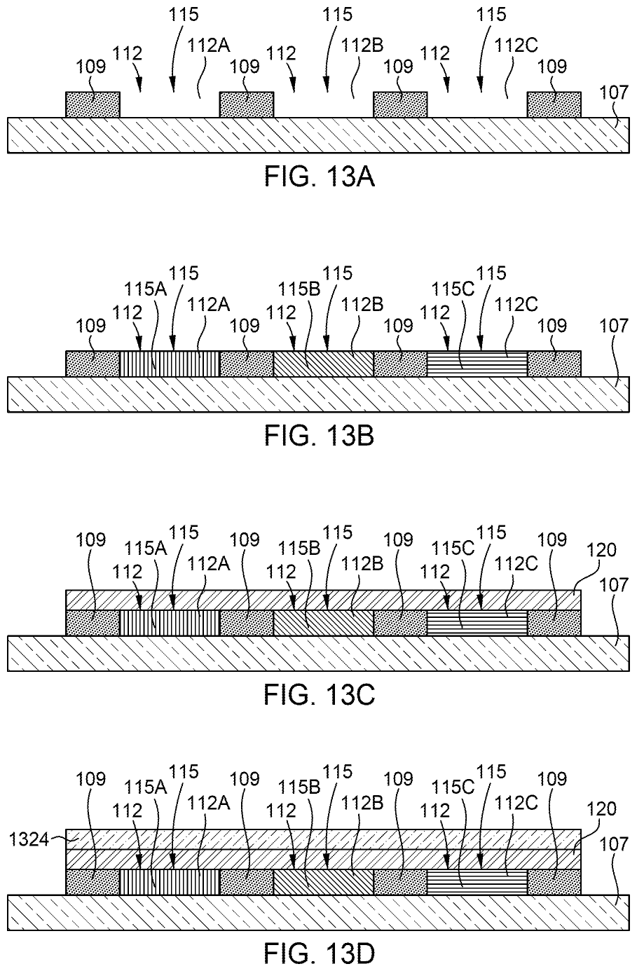

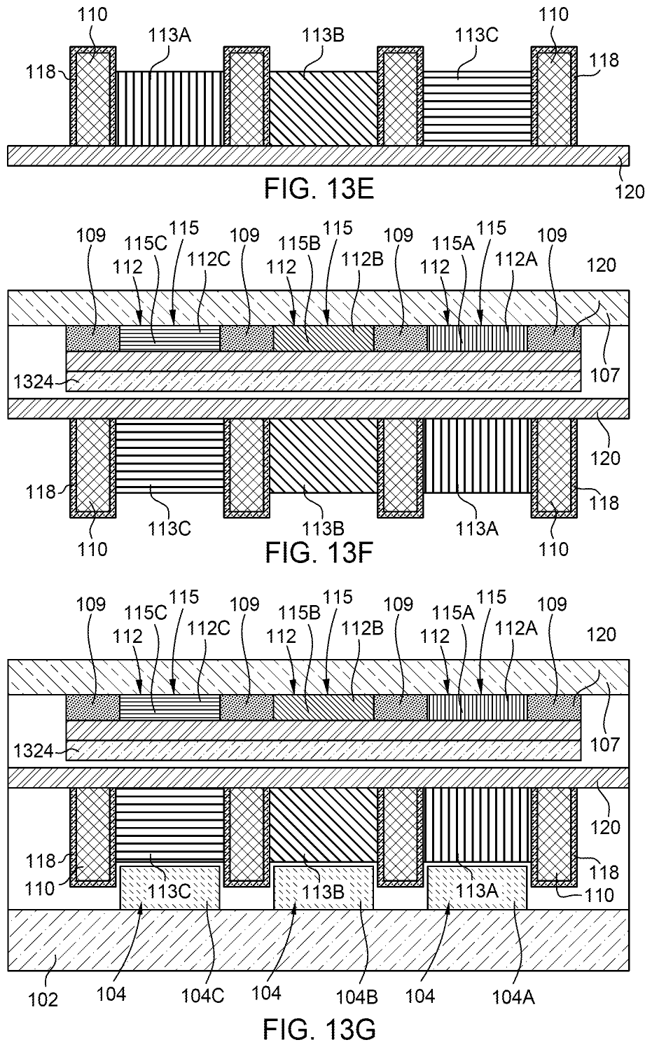

FIG. 12 illustrates a flow diagram of a method 1200 of forming a pixel 1100 having a fourth arrangement 1101A. FIGS. 13A-13G illustrate schematic, cross-sectional views of a pixel 1100 during the method 1200 of forming a pixel 1100 having a fourth arrangement 1101A.

At operation 1201, as shown in FIG. 13A, the plurality of black matrix structures 109 are patterned over a color resist transparent layer 1107A. The black matrix structures 109 may be patterned by a lithography process. The black matrix structures 109 define the plurality of color resist wells 115 of a sub-pixel 112, e.g. a color resist well 115 of a first sub-pixel 112A, a color resist well 115 of a second sub-pixel 112B, and a color resist well 115 of a third sub-pixel 112C.

At operation 1202, as shown in FIG. 13B, a color resist is disposed in the plurality of color resist wells 115. A first color resist 115A is disposed in a color resist well 115 of a first sub-pixel 112A, a second color resist 115B is disposed in a color resist well 115 of a second sub-pixel 112B, and a third color resist 115C is disposed in a color resist well 115 of a third sub-pixel 112C. The color resists are disposed using an inkjet printing process.

At operation 1203, as shown in FIG. 13C, a capping layer is disposed over the black matrix structures 109 and the color resists (e.g., the first color resist 115A, the second color resist 115B, and the third color resist 115C). The capping layer 120 is disposed over the black matrix structure 109 and the color resists using a physical vapor deposition (PVD) process, a chemical vapor deposition (CVD) process, or other deposition process.

At operation 1204, as shown in FIG. 13D, an ultraviolet (UV) blocking layer 624 is disposed over the capping layer 120. The UV blocking layer is disposed using a chemical vapor deposition (CVD) process, an atomic layer deposition (ALD) process, or a spin coating process.

At operation 1205, as shown in FIG. 13E, the plurality of sub-pixel isolation structures 110 are disposed over a color conversion transparent layer 107B. The sub-pixel isolation structures define the plurality of color conversion wells 113. A color conversion material is disposed in the plurality of color conversion well 113, e.g., a first color conversion material 113A is disposed in the color conversion well 113 of the first sub-pixel 112A, a second color conversion material 113B is disposed in the color conversion well 113 of the second sub-pixel 112B, and a third color conversion material 113C is disposed in the color conversion well 113 of the third sub-pixel 112C.

At operation 1206, as shown in FIG. 13F, the color resist transparent layer 1107A is bonded to the color conversion transparent layer 1107B to form a color panel 1105. A first adhesive bonds the color resist transparent layer 1107A and the color conversion transparent layer 1107B.

At operation 1207, as shown in FIG. 13G, the color panel 1105 is bonded to a LED panel 103. A second adhesive material 11066 bonds the color panel 1105 to the LED panel 103. The LED panel 103 includes a backplane 102 and the plurality of micro-LEDs 104 disposed on the backplane 102. The plurality of micro-LEDs 104 may include a first micro-LED 104A corresponding to a first sub-pixel 112A, a second micro-LED 104B corresponding to a second sub-pixel 112B, and a third micro-LED 104C corresponding to a third sub-pixel 112C.

While the foregoing is directed to embodiments of the present disclosure, other and further embodiments of the disclosure may be devised without departing from the basic scope thereof, and the scope thereof is determined by the claims that follow.

What is claimed is:

1. A pixel, comprising:
a color panel, comprising:
a transparent layer;
a plurality of sub-pixel isolation structures, wherein the plurality of sub-pixel isolation structures define a plurality color conversion wells of a plurality of sub-pixels, the plurality of color conversion wells comprising:
a first color conversion well of a first sub-pixel;
a second color conversion well of a second sub-pixel; and
a third color conversion well of a third sub-pixel;
a first color conversion material is disposed within the first color conversion well;
a second color conversion material is disposed within the second color conversion well;
a third color conversion material is disposed within the third color conversion well;
a plurality of black matrix structures disposed between the plurality of sub-pixel isolation structures and the transparent layer, wherein the plurality of black matrix structures define a plurality of color resist wells of the plurality of sub-pixels, the plurality of color resist wells comprising:
a first color resist well of the first sub-pixel;
a second color resist well of the second sub-pixel; and
a third color resist well of the third sub-pixel; and
a light emitting diode (LED) panel, comprising:
a plurality of micro-LEDs, wherein a first micro-LED of the plurality of micro-LEDs corresponds to the first sub-pixel, a second micro-LED of the plurality of micro-LEDs corresponds to the second sub-pixel, a third micro-LED of the plurality of micro-LEDs corresponds to the third sub-pixel; and
a backplane, wherein the plurality of micro-LEDs are disposed on the backplane; and
an adhesive material disposed between the LED panel and the color panel.

2. The pixel of claim 1, further comprising:
a capping layer disposed between the plurality of sub-pixel isolation structures and the plurality of black matrix structures; and
an ultraviolet (UV) blocking layer disposed between the plurality of sub-pixel isolation structures and the capping layer.

3. The pixel of claim 1, further comprising:
a capping layer disposed between the plurality of sub-pixel isolation structures and the plurality of black matrix structures; and
an ultraviolet (UV) blocking layer disposed between the plurality of black matrix structures and the transparent layer.

4. The pixel of claim 1, wherein a coating material is disposed over the plurality of sub-pixel isolation structures.

5. The pixel of claim 1, wherein the first color conversion material is a red color conversion material, the second color conversion material is a green color conversion material, and the third color conversion material is a blue color conversion material.

6. The pixel of claim 1, wherein the first color resist is a red color resist, the second color resist is a green color resist, and the third color resist is a blue color resist.

7. A pixel, comprising:
a color panel, comprising:
a color resist transparent layer;
a color conversion transparent layer;
a plurality of sub-pixel isolation structures, wherein the plurality of sub-pixel isolation structures define a plurality of color conversion wells of a plurality of sub-pixels, the plurality of color conversion wells comprising:
a first color conversion well of a first sub-pixel;
a second color conversion well of a second sub-pixel; and
a third color conversion well of a third sub-pixel;
a first color conversion material is disposed within the first color conversion well;
a second color conversion material is disposed within the second color conversion well;
a third color conversion material is disposed within the third color conversion well;
a first adhesive material disposed between the color conversion transparent layer and the color resist transparent layer;
a plurality of black matrix structures disposed between the transparent layer and the sub-pixel isolation structures, wherein the plurality of black matrix structures define a plurality of color resist wells of the plurality of sub-pixels, plurality of color resist wells comprising:
a first color resist well of the first sub-pixel;
a second color resist well of the second sub-pixel; and
a third color resist well of the third sub-pixel; and
a light emitting diode (LED) panel, comprising:
a plurality of micro-LEDs, wherein a first micro-LED of the plurality of micro-LEDs corresponds to the first sub-pixel, a second micro-LED of the plurality of micro-LEDs corresponds to the second sub-pixel, a third micro-LED of the plurality of micro-LEDs corresponds to the third sub-pixel; and
a backplane, wherein the plurality of micro-LEDs are disposed on the backplane; and
a second adhesive material disposed between the LED panel and the color panel.

8. The pixel of claim 7, further comprising:
a capping layer disposed between the plurality of sub-pixel isolation structures and the plurality of black matrix structures; and
an ultraviolet (UV) blocking layer disposed between the plurality of sub-pixel isolation structures and the capping layer.

9. The pixel of claim 7, further comprising:
a capping layer disposed between the plurality of sub-pixel isolation structures and the plurality of black matrix structures; and
an ultraviolet (UV) blocking layer disposed between the plurality of black matrix structures and the transparent layer.

10. The pixel of claim 7, wherein a coating material is disposed over the plurality of sub-pixel isolation structures.

11. The pixel of claim 7, wherein the first color conversion material is a red color conversion material, the second color conversion material is a green color conversion material, and the third color conversion material is a blue color conversion material.

12. The pixel of claim 7, wherein the first color resist is a red color resist, the second color resist is a green color resist, and the third color resist is a blue color resist.

13. A method of making a pixel, the method comprising:
patterning a plurality of black matrix structures over a transparent layer;
disposing a color resist in the plurality of color resist wells defined by the black matrix structures;
disposing an isolation structure layer over the black matrix structures and the plurality of color resist wells;
patterning the isolation structure layer to form the plurality of sub-pixel isolation structures;
disposing a color conversion material in the plurality of color conversion wells to form a color panel, wherein the plurality of color conversion wells are defined by the plurality of sub-pixel isolation structures; and
bonding the color panel to a light emitting diode (LED) panel, the LED panel comprising the plurality of micro-LEDs disposed over a backplane.

14. The method of claim 13, further comprising:
disposing a coating material over the plurality of sub-pixel isolation structures.

15. The method of claim 13, further comprising:
disposing a capping layer over the black matrix structures and the plurality of color resist wells;
disposing a UV blocking layer over the capping layer.

16. The method of claim 13, further comprising:
disposing a capping layer over the black matrix structures and the plurality of color resist wells;
disposing a UV blocking layer over the transparent layer.

17. The method of claim 13, wherein the transparent layer is a color resist transparent layer, further comprising:
disposing a capping layer over the black matrix structures and the plurality of color resist wells;
disposing a second adhesive material over the capping layer; and
disposing a color conversion transparent layer over the second adhesive material.

18. The method of claim 13, wherein the color conversion material comprises:
a first color conversion material disposed in a color conversion well of a first sub-pixel;
a second color conversion material disposed in a color conversion well of a second sub-pixel; and
a third color conversion material disposed in a color conversion well of a third sub-pixel.

19. The method of claim 18, wherein the first color conversion material is a red color conversion material, the second color conversion material is a green color conversion material, and the third color conversion material is a blue color conversion material.

20. The method of claim 13, further comprising:
a first color resist well of a first sub-pixel;
a second color resist well of a second sub-pixel; and
a third color resist well of a third sub-pixel.
